(19) United States
(12) Patent Application Publication
(10) Pub. No.: US 2021/0028115 A1
(43) Pub. Date: Jan. 28, 2021

(54) LOW PARASITIC MIDDLE-OF-LINE SCHEME

(71) Applicant: QUALCOMM Incorporated, San Diego, CA (US)

(72) Inventors: Junjing BAO, San Diego, CA (US); Peijie FENG, San Diego, CA (US); Haining YANG, San Diego, CA (US); Jun YUAN, San Diego, CA (US)

(21) Appl. No.: 16/517,845

(22) Filed: Jul. 22, 2019

(51) Int. Cl. H01L 23/532; H01L 23/535; H01L 29/45; H01L 21/768

(52) U.S. Cl. CPC H01L 23/5329; H01L 23/535; H01L 23/53266; H01L 21/76895; H01L 23/53209; H01L 29/45; H01L 21/7682; H01L 23/53252

(57) ABSTRACT

Certain aspects of the present disclosure generally relate to an integrated device including a low parasitic middle-of-line (MOL) structure. The integrated device generally includes a plurality of semiconductor devices; an MOL structure disposed above the plurality of semiconductor devices and comprising a dielectric layer; a first barrier-less conductor extending between a first terminal of a semiconductor device in the plurality of semiconductor devices and into the MOL structure; and a first air gap disposed between a lateral surface of an upper portion of the first barrier-less conductor and the dielectric layer of the MOL structure.

### TECHNICAL FIELD

Certain aspects of the present disclosure generally relate to electronic components and, more particularly, to a low parasitic middle-of-line (MOL) scheme for integrated circuits.

### BACKGROUND

Computing devices have become commonplace throughout society. The increasing presence of such computing devices has accelerated in part because of the increasing functionality and versatility of such computing devices. The increase in functionality and versatility has been enabled by providing increasingly powerful processing capabilities in small packages as loosely recognized by Moore's Law. The pressures to increase processing capabilities while decreasing the size of the integrated circuits (ICs) have strained conventional manufacturing processes, especially as the node size within ICs has been reduced to low nanometer (nm) dimensions (e.g., <20 nm).

Current semiconductor fabrication of ICs may include front-end-of-line (FEOL), middle-of-line (MOL), and back-end-of-line (BEOL) processes, the results of which are illustrated in FIG. 5. The FEOL processes may include wafer preparation, isolation, well formation, gate patterning, spacer, extension, source/drain implantation, silicide formation, and the like. The MOL processes may include gate contact formation and local interconnection between a transistor and a first metal interconnect layer within an integrated circuit. The BEOL processes may include a series of wafer processing steps for interconnecting semiconductor devices created during the FEOL and MOL processes.

As integrated circuit device sizes decrease, the complexity of processes used to form local interconnects has increased. For example, MOL integration stages may use multiple masks and may have exacting specifications to align local interconnects with underlying transistor structures. Further, as the sizes of integrated circuit devices decrease, negative effects, such as parasitic capacitance between local interconnects, also tend to increase.

### SUMMARY

Certain aspects of the present disclosure are generally directed to an integrated circuit. The integrated circuit generally includes a plurality of semiconductor devices; a middle-of-line (MOL) structure disposed above the plurality of semiconductor devices and comprising a dielectric layer; a first barrier-less conductor extending between a first terminal of a semiconductor device in the plurality of semiconductor devices and into the MOL structure; and a first air gap disposed between a lateral surface of an upper portion of the first barrier-less conductor and the dielectric layer of the MOL structure.

Certain aspects of the present disclosure generally relate to a method for fabricating an integrated circuit. The method generally includes forming an MOL structure disposed above a plurality of semiconductor devices, the MOL structure comprising a dielectric layer; forming a first barrier-less conductor extending between a first terminal of a semiconductor device in the plurality of semiconductor devices and into the MOL structure; and forming a first air gap disposed between a lateral surface of an upper portion of the first barrier-less conductor and the dielectric layer of the MOL structure.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a cross-sectional view of a conventional middle-of-line (MOL) structure of an integrated circuit.

FIG. 2 illustrates an example cross-section of a low parasitic MOL structure, according to certain aspects presented herein.

FIG. 3A-I illustrate example operations for fabricating a low parasitic MOL structure, in accordance with certain aspects of the present disclosure.

FIG. 4 is a flow diagram illustrating example operations for fabricating a low parasitic MOL structure, in accordance with certain aspects of the present disclosure.

FIG. 5 illustrates an example cross-section of an integrated circuit including a substrate layer, a front-end-of-line (FEOL) layer, an MOL layer, and a bottom-end-of-line (BEOL) layer.

### DETAILED DESCRIPTION

Certain aspects of the present disclosure are generally directed to a low parasitic middle-of-line (MOL) scheme. An example integrated circuit (IC) implemented with this scheme generally includes a barrier-less conductor extending between a terminal of one of a plurality of semiconductor devices and into a MOL structure, as well as an air gap disposed between a lateral surface of an upper portion of the barrier-less conductor and a dielectric layer in the MOL structure.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

Certain terminology may also be used in the following description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

### EXAMPLE SEMICONDUCTOR DEVICE

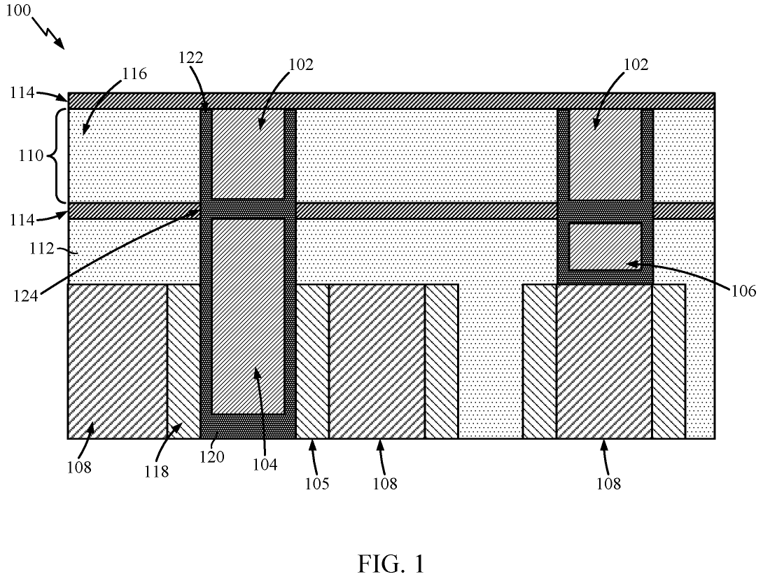

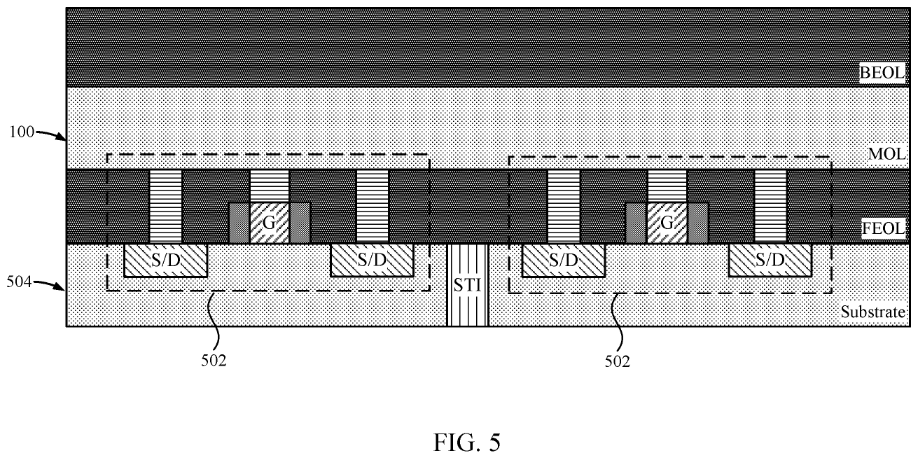

FIG. 1 illustrates a cross-section of a middle-of-line (MOL) structure 100 in a semiconductor device. The MOL structure 100 is situated above active layers of the semiconductor device, as illustrated in FIG. 5, and provides local interconnects (e.g., local contacts 102, 104, and 106) to portions of one or more semiconductor devices (e.g., transistors 502), such as diffusion regions (e.g., source, drain, and channel) embedded in a well region of a substrate layer 504 and gate structures 108 (e.g., gate stacks). For example, in some cases, local contact 104 may provide local contact to one of a source region or a drain region (labeled “S/D” in FIG. 5, whereas the gate is labeled “G”) of a transistor 502. Additionally, as illustrated, local contact 106 may provide local contact to gate 108 (e.g., a polysilicon conductor gate) of the transistor 502. Further, as illustrated, MOL structure 100 may include a local routing layer 110 that includes local contact 102 for providing local interconnection between a plurality of transistors of a cell.

Further, as illustrated, the MOL structure 100 may include a first dielectric layer 112, etch stop layers 114, and a second dielectric layer 116. The first dielectric layer 112 and the second dielectric layer 116 may be composed of any suitable dielectric material, such as silicon oxynitride (SiON) or silicon dioxide (SiO₂). Additionally or alternatively in some cases, one or more of the etch stop layers 114 may be composed of a material such as silicon carbon nitride (SiCN).

In some cases, local contact 104 may be composed of a material such as cobalt (Co) or tungsten (W) and may be situated between gates 108. Additionally, a spacer 118 may be deposited on either side of the local contact 104 to provide isolation from gates 108. In some cases, the spacer 118 may comprise any suitable dielectric material, such as silicon oxycarbide (SiOC) or silicon-boron-carbide-nitride (SiBCN). Additionally, the local contact 104 may be wrapped in an adhesion layer 120 (e.g., TiN) to improve bonding between the local contact 104 and the spacer 118 and first dielectric layer 112.

As illustrated, local contact 102 may be situated above local contact 104 and enables local interconnection between a plurality of transistors, at the cost of high parasitic resistance (+20%) and capacitance (+4%), which may cause low performance and/or high power. For example, local contact 104 may traditionally be formed by a single damascene etch and then metal fill (e.g., Co or W) and wrapped with a barrier layer 122 (e.g., TiN barrier (thickness of ˜2 nm)). However, as illustrated, the traditional method of forming local contact 102 with cobalt and/or tungsten creates an interface or diffusion barrier 124 between the local contact 102 and local contact 104. This diffusion barrier 124 causes high interface resistance between the local contact 102 and the local contact 104, which may be responsible for causing low performance. Additionally, MOL structure 100 may experience high parasitic capacitance due to the relatively high dielectric constant of the second dielectric layer 116 (e.g., SiO₂ with κ˜4.1) and the close distance between the local contact 102 and the gate 108, causing the MOL structure 100 to dissipate more power.

Thus, aspects of the present disclosure provide a MOL structure that reduces the parasitic resistance caused by barriers between local contacts and/or the high parasitic capacitance observed between certain local contacts and transistor gates. In some cases, reducing the parasitic resistance caused by barriers between local contacts may involve forming a barrier-less local contact that provides both local contact to one of a source region or a drain region of a transistor and local interconnection between transistors. In some cases, reducing the parasitic capacitance may involve forming air gaps on the sides of the local contact 102, lowering the dielectric constant of the material between the local contact 102 and the second dielectric layer 116, thereby resulting in less parasitic capacitance.

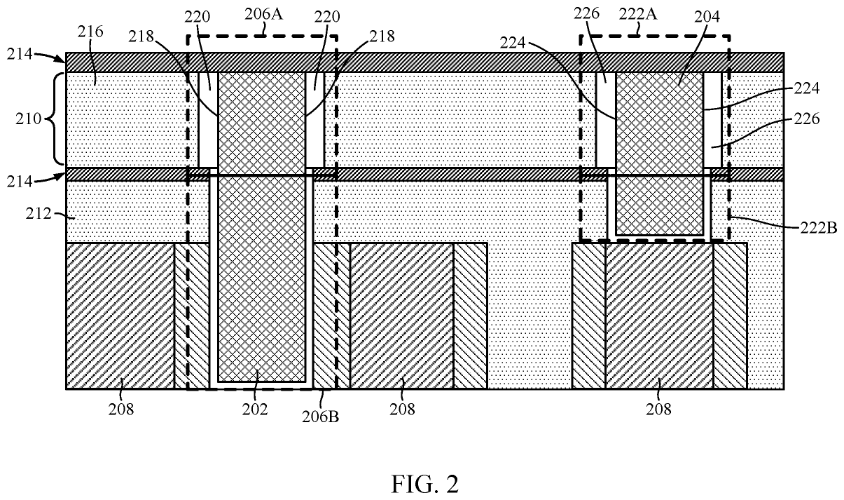

FIG. 2 illustrates an example cross-section of a MOL structure 200 for reducing parasitic resistance and capacitance, according to aspects presented here. As illustrated, the MOL structure 200 is similar to MOL structure 100 except in a few key aspects, described in detail below. For example, MOL structure 200 may be included in an integrated circuit that includes a plurality of semiconductor devices. As illustrated, the MOL structure 200 may be situated above and provides local interconnects (e.g., local contacts 202 and 204) to portions of one or more semiconductor devices (e.g., a transistor) of the plurality of semiconductor devices. For example, the MOL structure 200 may provide local interconnection to diffusion regions (e.g., source, drain, and channel regions) embedded in a well region of a substrate layer (e.g., via local contact 202) and gate structures 208 (e.g., via local contact 204). Further, as illustrated, MOL structure 200 may include a local routing layer 210 containing an upper portion 206A of the local contact 202 for providing local interconnection between a plurality of transistors of a cell.

As with MOL structure 100, MOL structure 200 includes a first dielectric layer 212, etch stop layers 214, and a second dielectric layer 216. The first dielectric layer 112 and the second dielectric layer 116 may be composed of any suitable dielectric material such as silicon oxynitride (SiON) or silicon dioxide (SiO₂). Additionally or alternatively in some cases, the etch stop layers 114 may be composed of a material such as silicon carbon nitride (SiCN).

According to aspects, to reduce the parasitic resistance between local contacts (e.g., as observed between local contacts 102 and 104 in FIG. 1), the MOL structure 200 provides a barrier-less local contact 202 that extends between a terminal (e.g., a source region or drain region) of one or more semiconductor devices below the MOL structure 200 and into the MOL structure 200.

For example, as illustrated, the local contact 202 may comprise an upper portion 206A and a lower portion 206B. The upper portion 206A is similar to the local contact 102 in FIG. 1 in that the upper portion 206A provides interconnection between transistors of a cell. Additionally, the lower portion 206B is similar to local contact 104 in FIG. 1 in that lower portion 206B provides local contact to one or more terminals of a semiconductor device, such as a source region or drain region. Thus, as illustrated, the local contact 202 may be considered a combination of two local contacts. For example, as illustrated, the local contact 202 may be composed of a first local contact (e.g., upper portion 206A) and a second local contact (e.g., lower portion 206B) that share the same conductor.

Further, as illustrated, unlike local contacts 102 and 104 in FIG. 1, local contact 202 does not include a barrier or interface between upper portion 206A and lower portion 206B. According to aspects, to accomplish this barrier-less local contact, the local contact 202 may be composed of a barrier-less conductor, such as ruthenium (Ru), which, unlike cobalt and tungsten, does not involve using an adhesion layer between applications. With a barrier-less contact, parasitic resistance is reduced since electric current flowing through the local contact 202 does not have to pass through a barrier unlike for local contacts 102 and 104 in FIG. 1, thereby increasing performance of the MOL structure 200.

Additionally, to reduce the parasitic capacitance due to the relatively high dielectric constant of the second dielectric layer 216 (e.g., SiO₂ κ˜4.1) and the close distance between the upper portion 206A of the local contact 202 and the gates 108, air gaps 220 may be disposed between the upper portion 206A of the local contact 202 and the second dielectric layer 216. For example, as illustrated, air gaps 220 may be disposed between the lateral surface(s) 218 (e.g., vertical sidewalls) of the upper portion 206A of the local contact 202 and the second dielectric layer 216. According to aspects, because the dielectric constant of air is relatively low (e.g., κ˜1.0) as compared to the dielectric constant of the material composing the second dielectric layer 216 (e.g., SiO₂ κ˜4.1), the air gaps 220 reduce the parasitic capacitance caused by the second dielectric layer 216 and gate 208.

The techniques described above may also be applied to local contact 204. For example, as illustrated local contact 204 may provide local contact to another terminal (e.g., gate 208) of a semiconductor device in the plurality of semiconductor devices (e.g., transistors). Additionally, local contact 204 may comprise an upper portion 222A and a lower portion 222B. According to aspects, to remove the barrier that may be formed during traditional fabrication methods (and thereby reduce parasitic capacitance between the upper portion 222A and lower portion 222B), the local contact 204 may be composed of a barrier-less conductor, such as ruthenium (Ru), which, unlike cobalt and tungsten, does not entail using a barrier layer between applications, as noted above. Thus, as illustrated, local contact 204 does not include a barrier between the upper portion 222A and 222B, unlike the barrier between local contacts 102 and 106 illustrated in FIG. 1.

Additionally, as with local contact 202, air gaps 226 may be disposed between the lateral surface(s) 224 (e.g., vertical sidewalls) of the upper portion 222A of the local contact 204 and the second dielectric layer 216 As noted above, air gaps 226 may reduce the parasitic capacitance between the local contact 204 and gate structures 208 due to the second dielectric layer 216.

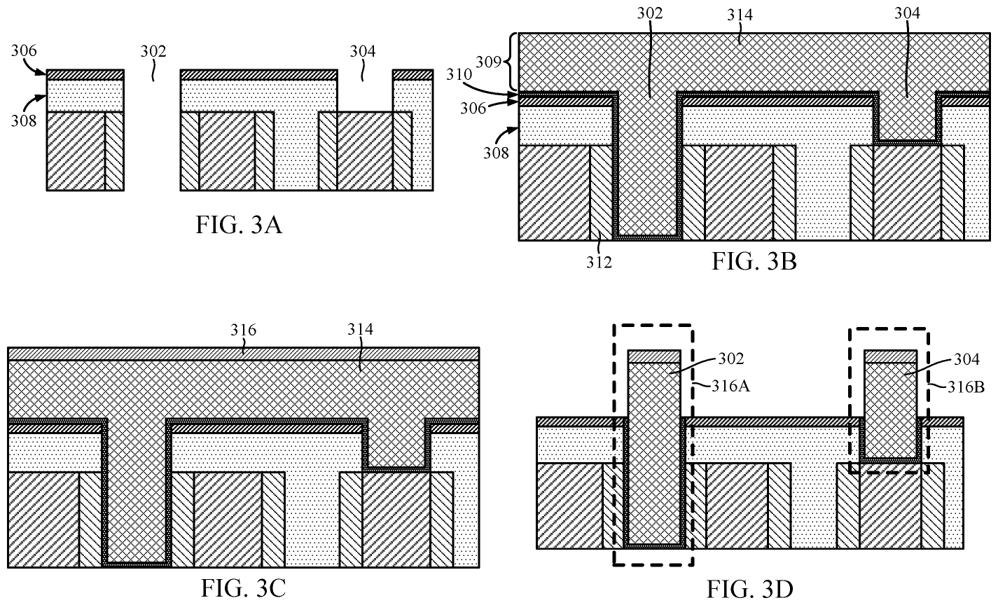

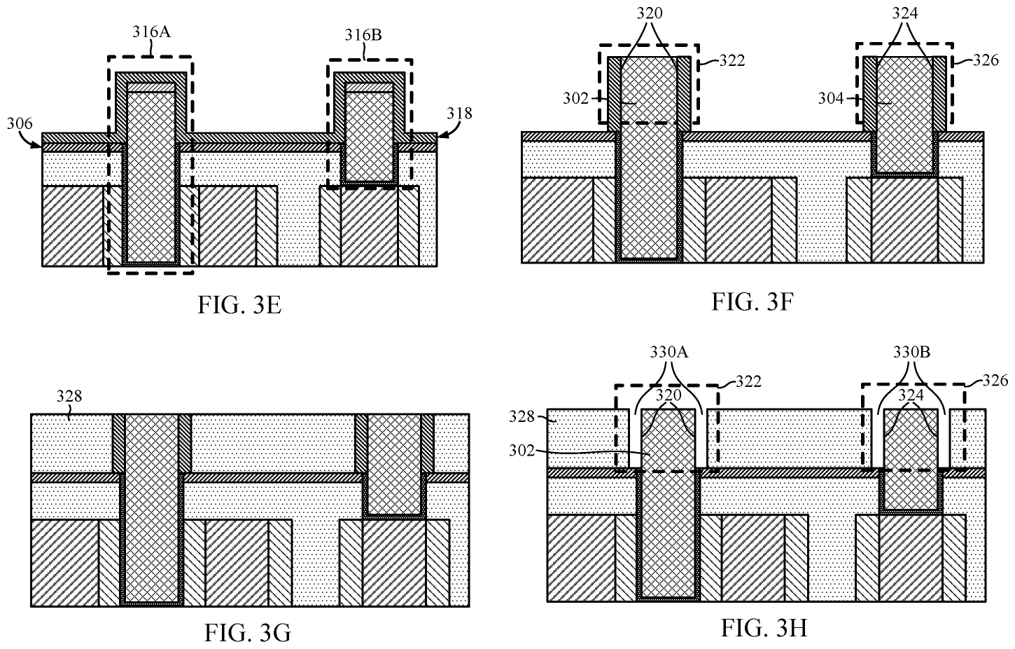

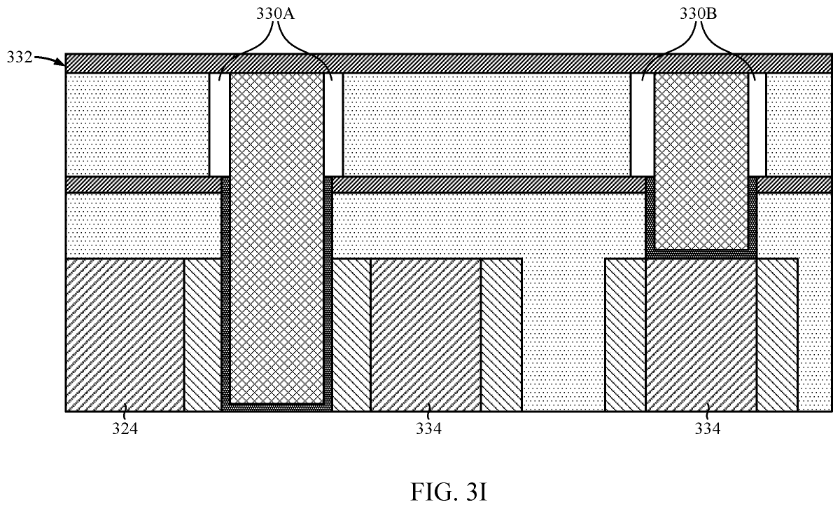

FIGS. 3A-I illustrate example operations for fabricating the MOL structure 200, in accordance with certain aspects of the present disclosure. As illustrated in FIG. 3A, the fabrication process may begin with an incoming wafer that includes a pre-formed local contact pattern corresponding to local contact 302 and local contact 304. According to aspects, local contacts 302 and 304 may correspond to local contacts 202 and 204, respectively. As above, local contact 302 will provide both interconnection between transistors of a cell and local contact to one or more terminals of a semiconductor device, such as a source region or drain region. Local contact 304 will provide local contact to one or more other terminals, such as a gate structure, corresponding to the semiconductor device. Additionally, as illustrated in FIG. 3A, an etch stop layer 306 (e.g., SiCN, with a thickness of ˜10 nm) may be deposited on top of a first dielectric layer 308.

According to aspects, as illustrated in FIG. 3B, an adhesion layer 310 may then be deposited on the top surfaces of the etch stop layer 306 and exposed lateral surfaces of the first dielectric layer 308 and spacers 312 in the trenches that will later become local contacts 302 and 304. In some cases, the adhesion layer may be composed of a material such as titanium nitride (TiN) and be approximately 0.3-1.0 nm thick. Thereafter, chemical vapor deposition or another suitable deposition technique may be performed to deposit a barrier-less conductor layer 314. As illustrated, deposition of the conductor layer 314 may fill in the trenches corresponding to local contacts 302 and 304 and create the local routing layer 309 (e.g., which provides interconnection between transistors of a cell). According to aspects, the barrier-less conductor layer 314 may be composed of a material such as ruthenium, which allows for the creation of local contacts 302 and 304 without barriers or interfaces, as discussed above. In some cases, other materials such as rhodium (Rh), platinum (Pt), iridium (Ir), niobium (Nb), nickel (Ni), molybdenum (Mo), or osmium (Os) may be used to form the barrier-less conductor layer 314. According to aspects, since the local contacts 302 and 304 do not have any barriers, parasitic resistance may be reduced, increasing performance of the MOL structure 200, as discussed above. According to aspects, chemical-mechanical polishing (CMP) may then be performed to adjust the height of the local routing layer 309.

As illustrated in FIG. 3C, after the barrier-less conductor layer 314 is deposited, a hard mask layer 316 may then be applied on the top surface of the barrier-less conductor layer 314.

As illustrated in FIG. 3D, a subtractive etch may be performed using a photo mask to remove unwanted portions of the adhesion layer 310 and barrier-less conductive layer 314 to create conductive pillars 316A and 316B corresponding to local contacts 302 and 304, respectively.

In FIG. 3E, a sacrificial layer 318 may be conformally grown on top of the etch stop layer 306 and exposed sides of the conductive pillars 316A and 316B. As will be discussed in more detail below, the sacrificial layer 318 will serve as the basis for creating the air gaps discussed above. According to aspects, the sacrificial layer 318 may be composed of any suitable material, such as carbon-doped silicon oxide (SiCOH).

As illustrated in FIG. 3F, an anisotropic etch may be performed to remove the sacrificial layer 318 and the hard mask layer 316 from all surfaces except the lateral surfaces (e.g., sidewalls 320) of an upper portion 322 of the local contact 302 and lateral surfaces (e.g., sidewalls 324) of an upper portion 326 of the local contact 304.

Thereafter, in FIG. 3G, flowable chemical vapor deposition may be performed to deposit a second dielectric layer 328. According to aspects, the second dielectric layer 328 may comprise any suitable dielectric material, such as silicon dioxide (SiO₂).

As illustrated in FIG. 3H, the remaining sacrificial layer 318 may then be removed (e.g., burned or etched) from the sidewalls 320 and 324, leaving an air gap 330A between the second dielectric layer 328 and the sidewalls 320 of the upper portion 322 of the local contact 302 and an air gap 330B between the second dielectric layer 328 and the sidewalls 324 of the upper portion 326 of the local contact 304.

In FIG. 3I, a second etch stop layer 332 may then be deposited on top of the MOL structure 200, sealing the air gaps 330A and 330B. As noted above, because the dielectric constant of air is relatively low as compared to the material of the second dielectric layer 328 (e.g., air κ˜1.0 vs. SiO₂ κ˜4.1), the parasitic capacitance between the local contacts 302, 304 and the gate structures 334 (e.g., corresponding to gate structure 208) may be reduced, increasing the performance of the integrated circuit using the MOL structure 200.

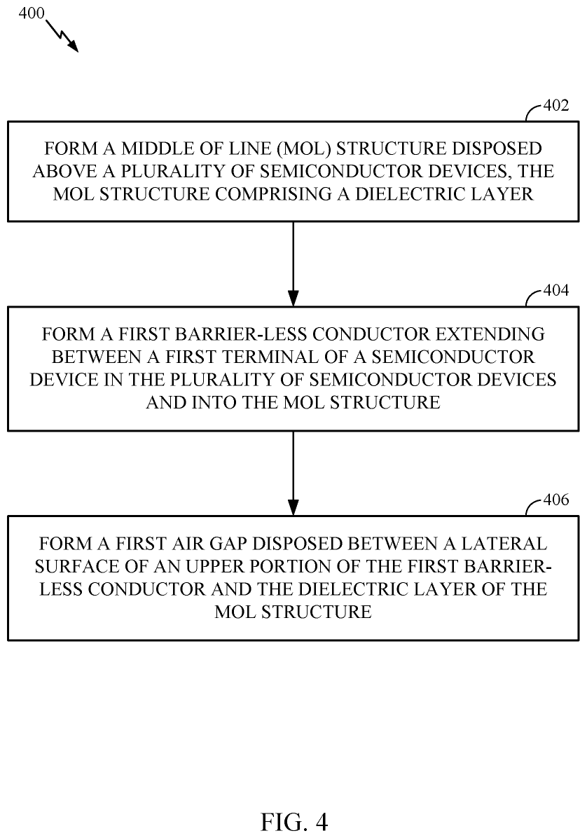

FIG. 4 is a flow diagram illustrating example operations 400 for fabricating an integrated circuit with a connective structure, such as a MOL structure 200, in accordance with certain aspects of the present disclosure. The operations 400 may be performed, for example, by a semiconductor processing facility.

The operations 400 begin, at block 402, with the semiconductor processing facility forming a middle-of-line (MOL) structure disposed above a plurality of semiconductor devices and comprising a dielectric layer.

At block 404, the semiconductor processing facility forms a first barrier-less conductor extending between a first terminal of a first semiconductor device of the plurality of semiconductor devices and into the MOL structure.

At block 406, the semiconductor processing facility forms a first air gap disposed between a first lateral surface of a first upper portion of the first barrier-less conductor and the dielectric layer in the MOL structure.

According to certain aspects, the first air gap completely surrounds all one or more lateral surfaces of the upper portion of the first barrier-less conductor.

Additionally, in some cases, the first barrier-less conductor comprises a local contact to the first terminal of the semiconductor device. In some cases, the first barrier-less conductor further provides a local interconnection between the plurality of semiconductor devices.

Further, in some cases, the operations 400 include forming a second barrier-less conductor extending between a second terminal of the semiconductor device and into the MOL structure. According to aspects, at least one of the first barrier-less conductor or the second barrier-less conductor is composed primarily of ruthenium, rhodium, platinum, iridium, niobium, nickel, molybdenum, or osmium.

According to certain aspects, the first terminal comprises one of a source region or a drain region of the semiconductor device, and the second terminal comprises a gate structure of the semiconductor device. Additionally, in some cases, the second barrier-less conductor provides a local contact to the second terminal of the semiconductor device.

Additionally, in some cases, the operations 400 further include forming a second air gap disposed between a lateral surface of an upper portion of the second barrier-less conductor and the dielectric layer in the MOL structure. In some cases, the second air gap completely surrounds all one or more lateral surfaces of the upper portion of the second barrier-less conductor.

Additionally, in some cases, the operations 400 further include forming a first adhesion layer surrounding a lower portion of the first barrier-less conductor. The operations 400 may additionally or alternatively include forming a second adhesion layer surrounding a lower portion of the second barrier-less conductor. The first adhesion layer and/or the second adhesion layer may be primarily composed of titanium nitride (TiN).

In some cases, the lateral surface of the upper portion of the first barrier-less conductor comprises a vertical sidewall thereof. Additionally, in some cases, the lateral surface of the upper portion of the second barrier-less conductor comprises a vertical sidewall thereof.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. An integrated circuit comprising:
a plurality of semiconductor devices;
a middle-of-line (MOL) structure disposed above the plurality of semiconductor devices and comprising a dielectric layer;
a first barrier-less conductor extending between a first terminal of a semiconductor device in the plurality of semiconductor devices and into the MOL structure; and
a first air gap disposed between a lateral surface of an upper portion of the first barrier-less conductor and the dielectric layer of the MOL structure.

2. The integrated circuit of claim 1, wherein the first air gap completely surrounds all one or more lateral surfaces of the upper portion of the first barrier-less conductor.

3. The integrated circuit of claim 1, wherein the first barrier-less conductor provides a local contact to the first terminal of the semiconductor device.

4. The integrated circuit of claim 3, wherein the first barrier-less conductor further provides a local interconnection between two or more of the plurality of semiconductor devices.

5. The integrated circuit of claim 1, further comprising a second barrier-less conductor extending between a second terminal of the semiconductor device and into the MOL structure.

6. The integrated circuit of claim 5, wherein at least one of the first barrier-less conductor or the second barrier-less conductor is composed primarily of ruthenium, rhodium, platinum, iridium, niobium, nickel, molybdenum, or osmium.

7. The integrated circuit of claim 5, wherein:
the first terminal comprises one of a source region or a drain region of the semiconductor device; and
the second terminal comprises a gate structure of the semiconductor device.

8. The integrated circuit of claim 5, wherein the second barrier-less conductor provides a local contact to the second terminal.

9. The integrated circuit of claim 5, further comprising a second air gap disposed between a lateral surface of an upper portion of the second barrier-less conductor and the dielectric layer of the MOL structure, wherein the second air gap completely surrounds all one or more lateral surfaces of the upper portion of the second barrier-less conductor.

10. The integrated circuit of claim 5, further comprising:
a first adhesion layer surrounding a lower portion of the first barrier-less conductor; and
a second adhesion layer surrounding a lower portion of the second barrier-less conductor, wherein the first adhesion layer and the second adhesion layer are primarily composed of titanium nitride (TiN).

11. A method for fabricating an integrated circuit, comprising:
forming a middle-of-line (MOL) structure disposed above a plurality of semiconductor devices, the MOL structure comprising a dielectric layer;
forming a first barrier-less conductor extending between a first terminal of a semiconductor device in the plurality of semiconductor devices and into the MOL structure; and
forming a first air gap disposed between a lateral surface of an upper portion of the first barrier-less conductor and the dielectric layer of the MOL structure.

12. The method of claim 11, the first air gap completely surrounds all one or more lateral surfaces of the upper portion of the first barrier-less conductor.

13. The method of claim 11, wherein the first barrier-less conductor comprises a local contact to the first terminal of the semiconductor device.

14. The method of claim 13, wherein the first barrier-less conductor further provides a local interconnection between the plurality of semiconductor devices.

15. The method of claim 11, further comprising forming a second barrier-less conductor extending between a second terminal of the semiconductor device and into the MOL structure.

16. The method of claim 15, wherein at least one of the first barrier-less conductor or the second barrier-less conductor is composed primarily of ruthenium, rhodium, platinum, iridium, niobium, nickel, molybdenum, or osmium.

17. The method of claim 15, wherein:
the first terminal comprises one of a source region or a drain region of the semiconductor device; and
the second terminal comprises a gate structure of the semiconductor device.

18. The method of claim 15, wherein the second barrier-less conductor provides a local contact to the second terminal of the semiconductor device.

19. The method of claim 15, further comprising forming a second air gap disposed between a lateral surface of an upper portion of the second barrier-less conductor and the dielectric layer in the MOL structure, wherein the second air gap completely surrounds all one or more lateral surfaces of the upper portion of the second barrier-less conductor.

20. The method of claim 15, further comprising:
forming a first adhesion layer surrounding a lower portion of the first barrier-less conductor; and
forming a second adhesion layer surrounding a lower portion of the second barrier-less conductor, wherein the first adhesion layer and the second adhesion layer are primarily composed of titanium nitride (TiN).
